(19) United States
(12) Patent Application Publication
(10) Pub. No.: US 2012/0244723 A1
(43) Pub. Date: Sep. 27, 2012

(54) LASER DRILLING OF VIAS IN BACK CONTACT SOLAR CELLS

(75) Inventors: Jeff M. Franklin, Albuquerque, NM (US); James M. Gee, Albuquerque, NM (US)

(73) Assignee: APPLIED MATERIALS, INC., Santa Clara, CA (US)

(21) Appl. No.: 13/496,762

(22) PCT Filed: Sep. 17, 2010
(86) PCT No.: PCT/US10/49329

§ 371 Date: May 30, 2012

Related U.S. Application Data
(60) Provisional application No. 61/243,821, filed on Sep. 18, 2009.

(51) Int. Cl. H01L 21/268; B23K 26/00

(52) U.S. Cl. 438/795; 219/121.68; 257/E21.347

(57) ABSTRACT

Embodiments of the invention relate to methods and apparatus for laser drilling holes in a silicon substrate during the fabrication of back contact solar cells, such as emitter-wrap-through (EWT) solar cells. In one embodiment, the method and apparatus use a short focal length flat field lens and a dynamic scanning technique to accomplish single pulse drilling in the silicon substrate. The method and apparatus result in increased speed and quality of holes in an EWT solar cell substrate as compared to conventional apparatus and processes.

### BACKGROUND OF THE INVENTION

1. Field of the Invention

The present invention relates to laser drilling of vias in back contact solar cells, such as emitter-wrap-through (EWT) solar cells, using a combination of single pulse drilling, a short focal length flat field lens, and a dynamic scanning technique.

2. Description of the Related Art

The solar cell design in widespread use today has a p/n junction formed near the front surface, or surface that receives the light, which generates electron/hole pairs as light energy is absorbed in the formed cell. The conventional cell design has one set of electrical contacts on the front side of the cell, and a second set of electrical contacts on the back side of the solar cell. In a typical photovoltaic module these individual solar cells are interconnected electrically in series to increase the generated voltage. This interconnection is typically accomplished by soldering a conductive ribbon from the front side of one solar cell to the back side of an adjacent solar cell.

Back-contact solar cells have both the negative-polarity and positive-polarity contacts on the rear surface. Back-contact silicon solar cells have several advantages compared to conventional silicon solar cells. The first advantage is that back-contact cells have a higher conversion efficiency due to reduced or eliminated contact obscuration losses (sunlight reflected from contact grid is unavailable to be converted into electricity). The second advantage is that assembly of back-contact cells into electrical circuits is easier, and therefore cheaper, because both conductivity type contacts are on the same surface. As an example, significant cost savings compared to present photovoltaic module assembly can be achieved with back-contact cells by encapsulating the photovoltaic module and the solar cell electrical circuit in a single step. The last advantage of a back-contact cell is better aesthetics through a more uniform appearance. Aesthetics is important for some applications, such as building-integrated photovoltaic systems and photovoltaic sunroofs for automobiles. FIG. 1 illustrates a typical back-contact cell structure 100. A silicon substrate 101 may be n-type or p-type. Heavily doped emitters (n⁺⁺ 102 or p⁺⁺ 103) may be omitted in some designs. The p-type 105 and n-type 106 metal contacts are provided on the rear surface of the structure 100. Alternatively, the heavily doped emitters could directly contact each other on the rear surface in other designs. Rear-surface passivation 104 helps reduce loss of photogenerated carriers at the rear surface, and helps reduce electrical losses due to shunt currents at undoped surfaces between the contacts.

There are several approaches for making a back-contact silicon solar cell. These approaches include metallization wrap around (MWA), metallization wrap through (MWT), emitter wrap through (EWT), and back-junction structures. MWA and MWT have metal current collection grids on the front surface. These grids are, respectively, wrapped around the edge or through holes to the back surface in order to make a back-contact cell. The unique feature of EWT cells, in comparison to MWT and MWA cells, is that there is no metal coverage on the front side of the cell, which means that none of the light impinging on the cell is blocked, resulting in higher efficiencies. The EWT cell wraps the current-collection junction (“emitter”) from the front surface to the rear surface through doped conductive channels in the silicon substrate. “Emitter” refers to a heavily doped region in a semiconductor device.

Generally, EWT cells are formed using a laser to drill holes in a silicon substrate. The emitter (i.e., n⁺ junction on the surface of a p-type silicon substrate) is diffused into the front surface, rear surface, and the hole surfaces. Thus, a conductive channel, or via, is formed connecting the front surface and the rear surface substrate. The emitter typically has limited conductivity, with values typically between 30 and 150 ohms/square. A high density of vias (e.g., between 0.5 and 5 holes per square millimeter) is therefore necessary to limit the resistance losses due to current flow in the front emitter and in the vias. Thus, a 156 mm×156 mm EWT silicon solar cell may require up to 120,000 holes, which requires a significant amount of time to perform the laser processing steps.

A variety of lasers have been used to machine silicon, including infrared (IR) and ultraviolet (UV) wavelength lasers having pulse widths from femtoseconds to milliseconds. In order to achieve mass removal from silicon, the silicon substrate is typically brought well above vaporization temperature to cause ejection of silicon material in an ablation process. Conventionally, for fast machining of silicon, a high power density (i.e., greater than 30 GW/cm²) is used, whereby a superheated volume causes ejection of liquid silicon drops through explosive boiling. An example of such machining is described in Quanming Lu, et al., “Delayed phase explosion during high-power nanosecond laser ablation of silicon,” Appl. Phys. Lett. 80, 3072 (2002).

Ejected material from laser machining also causes plasma to form above the silicon substrate. The resulting plasma has the effect of reducing the laser power density on the silicon substrate through reflection and absorption losses. In order to combat this effect, an inert gas blanket may be supplied to reduce the plasma density, resulting in less reduction of laser power loss due to the interaction of the laser beam and the generated plasma. Water and other liquid coatings have also been found to be useful for improving laser machining rate, as described in J. Ren, M. Kelly, and L. Hellelink, “Laser ablation of silicon in water with nanosecond and femtosecond pulses,” Opt. Lett. 30, 648 (2005). Such liquid coatings help improve the optical coupling of laser energy into the silicon substrate by reducing the reflectance, in turn, reducing the plasma density by excluding oxygen from the hot surface of the silicon substrate.

A laser and scanning system for drilling via holes in silicon needs to have high throughput, high quality (i.e., minimal residual damage and debris must be easily removed), good precision and high accuracy in the hole pattern so that subsequent solar cell patterns (i.e., emitter diffusion and metal contacts/grids) can be accurately aligned, and low capital and operating costs. One of the limiting factors for laser process throughput is the number of pulses required to drill each via hole. According to conventional methods, a lens having a focal length that provides a scan area equal to or exceeding the size of the substrate to be drilled is provided. For example, conventionally, a lens having a focal length of at least 256 mm would be used for drilling a pattern of holes over the entire surface of a 156 mm×156 mm substrate. However, the resulting power densities are too low to punch through a typical EWT solar cell substrate. As a result, multiple pass drilling is required, which significantly reduces throughput. Thus, improved methods and apparatus for drilling via holes in a substrate, such as a back contact solar cell substrate are needed.

### SUMMARY OF THE INVENTION

In one embodiment, a method of forming holes through a substrate comprises forming a first pattern of holes through a first section of the substrate using a laser scanner, positioning the laser scanner over a second section of the substrate adjacent the first section, and forming a second pattern of holes through the second section of the substrate, wherein each hole is formed with a single laser pulse.

In another embodiment, an apparatus for forming a pattern of holes through a substrate comprises a positioning table configured to hold and laterally move the substrate, a laser scanner configured with a scan area that is less than half of the surface area of the substrate, wherein the laser scanner is configured to form a pattern of holes through a first section of the substrate without moving the substrate or the laser scanner, and wherein the laser scanner is configured to form each hole with a single laser pulse.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is an illustration of a generic back-contact solar cell, highlighting only features on the back surface.

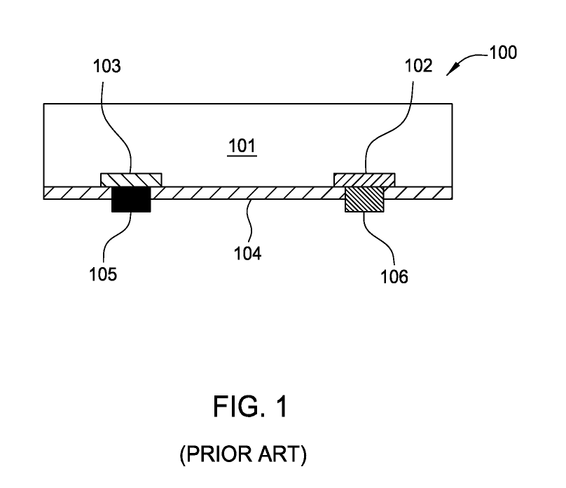

FIG. 2 is a schematic, side view of an apparatus according to an embodiment of the present invention.

FIG. 3 is a schematic, top view of the substrate positioned on the positioning table of FIG. 2 for use in performing a laser drilling process according to one embodiment.

FIG. 4 is a schematic, top view of the substrate positioned on the positioning table of FIG. 2 for use in performing a laser drilling process according to another embodiment.

FIG. 5 is a schematic, top view of the substrate positioned on the positioning table for use in performing a laser drilling process according to another embodiment.

FIG. 6 is a schematic, top view of the substrate positioned on a stationary table for use in performing a conventional laser drilling process.

FIG. 7 is a chart comparing the processing times of the processes described in examples 1-4 with respect to FIGS. 3-6.

For clarity, identical reference numerals have been used, where applicable, to designate identical elements that are common between figures. It is contemplated that features of one embodiment may be incorporated in other embodiments without further recitation.

### DETAILED DESCRIPTION OF THE INVENTION

The invention relates to a method and apparatus for laser drilling holes in a silicon substrate during the fabrication of back contact solar cells, such as emitter-wrap-through (EWT) solar cells. In one embodiment, the method and apparatus use a short focal length flat field lens and a dynamic scanning technique to accomplish single pulse drilling in the solar cell substrate. The method and apparatus result in increased speed and quality of holes in an EWT solar cell substrate as compared to conventional apparatus and processes. Solar cell devices that may benefit from the ideas disclosed herein may include devices formed on substrates comprising single crystal silicon, multi-crystalline silicon, polycrystalline silicon, germanium (Ge), gallium arsenide (GaAs), cadmium telluride (CdTe), cadmium sulfide (CdS), copper indium gallium selenide (CIGS), copper indium selenide (CuInSe₂), gallium indium phosphide (GaInP₂), as well as heterojunction cells, such as GaInP/GaAs/Ge, ZnSe/GaAs/Ge or other similar substrate materials that can be used to convert sunlight to electrical power. In one embodiment, the solar cell substrate comprises single crystal silicon, multi-crystalline silicon, or polycrystalline silicon.

One of the limiting factors for laser drilling process throughput is the number of pulses required to drill each via hole. In general, a lens with a shorter focal length enables smaller spot size and higher power densities, but the shorter focal length lens has a smaller field of view and more limited depth of focus. Thus, short focal length lenses are not able to be used to provide a hole pattern over the entire surface of a typical EWT solar cell substrate. In one example, the EWT solar cell substrate is at least 156 mm×156 mm×3 mm.

Use of a long focal length lens generally enables a larger field of view so that fast movement of the laser spot can be performed with a galvanometer-based mirror scanner (hereinafter, “scanner”). However, the use of long focal length lenses require the use of multiple pulses to form each hole. Thus, the scanner must either be stopped at each point in a pattern of holes to achieve multiple pulses at the same location to form the hole, resulting in extended processing time, or the scanner must precisely scan the pattern multiple times on each substrate, resulting in a greater chance of damaging the substrate from alignment errors between passes.

In one embodiment of the present invention, a short focal length lens is used to provide a higher concentration of energy from each laser pulse to more efficiently remove material from a silicon substrate. The short focal length results in a high power density with a small beam diameter at the focal point. Thus, drilling a hole for each via is possible with a single pulse. To take advantage of high repetition rates the scanner is run in a dynamic drilling mode. In this mode, the scanner does not stop at each hole location; rather, the pitch of the vias is determined by the pulse rate and the speed of the movement of the mirrors in the scanner. Thus, the dynamic mode allows the holes for the vias to be drilled much faster within a given field of view. The field of view is then rapidly repositioned to a different section of the substrate to complete the drilling process. In one embodiment, the field of view is repositioned to a different section of the substrate using a gantry method or a motorized X/Y table.

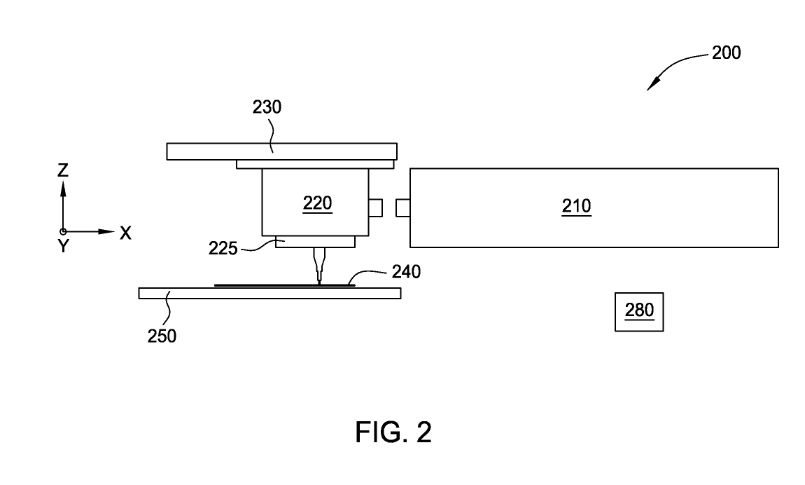

FIG. 2 is a schematic, side view of an apparatus 200 according to an embodiment of the present invention. A laser source 210 is provided and supplies pulses of electromagnetic energy into a galvanometer-based scanner 220. The laser source 210 may be a Q-switched laser operating in the infrared wavelengths, such as a wavelength of 1030 nm. In one embodiment, the laser source 210 produces a long pulse, such as a pulse width of about 1.5 μs or greater having a total energy of from about 4 to about 6 mJ/pulse. In one embodiment, the pulse width and frequency is controlled by use of a water cooled shutter that is disposed between the laser and the substrate. The scanner 220 is a conventional galvanometer-based scanner having a galvanometer, one or more mirrors (e.g., an X mirror and a Y mirror), and a servo driver board that controls the system. The scanner 220 is configured to direct a pattern of pulses in the X-Y plane within the field of view of a lens 225 attached thereto. The lens 225 may be a short focal length lens, such as 163 mm or 100 mm.

The scanner 220 may be mounted to a positioning gantry 230. In one embodiment, the positioning gantry 230 includes a rail and an actuator (e.g., linear motor) to provide movement of the scanner 220 only in the X-direction. In another embodiment, the positioning gantry 230 is an X-Y positioning system.

A substrate 240, such as an EWT solar cell substrate, is positioned on a positioning table 250 beneath the scanner 220. In one embodiment, the positioning table 250 is a conventional X-Y positioning table having one or more actuators (e.g., linear motor) configured to move the substrate 240 in both the X and Y directions.

A system controller 280 is used to control and coordinate the motion of the X-Y positioning table 250, the positioning gantry 230, the scanner 220, and the laser 210 output (e.g., water cooled shutter). The system controller 280 includes a memory (not shown), a central processing unit (CPU) (not shown), and support circuits (not shown) that are coupled to each of the controlled components of the apparatus 200.

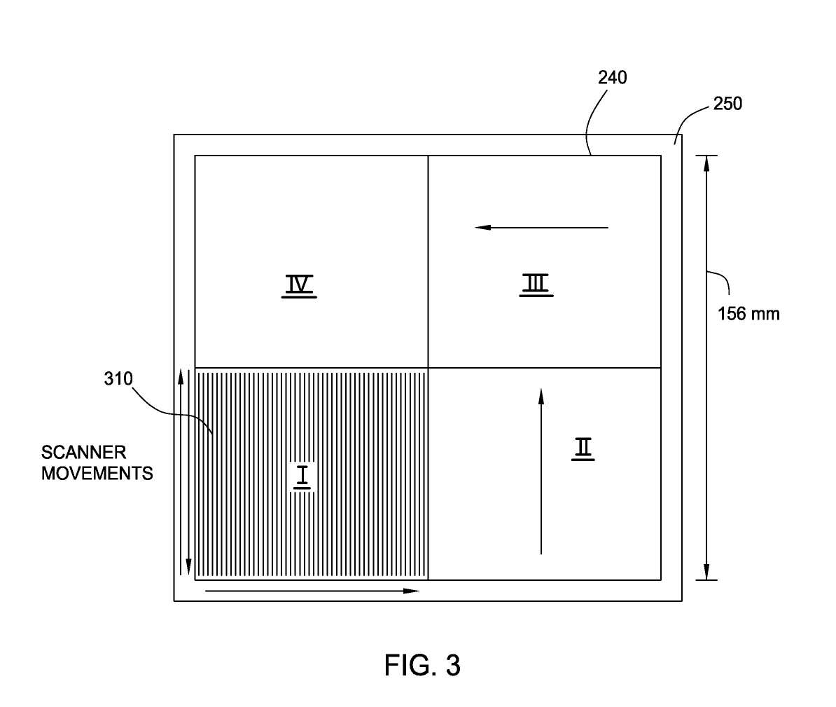

FIG. 3 is a schematic, top view of the substrate 240 positioned on the positioning table 250 for use in performing a laser drilling process according to one embodiment. In one embodiment, the substrate 240 is a 156 mm×156 mm silicon substrate having a thickness of between about 150 μm to about 300 μm. The substrate 240 is schematically shown divided into quadrants I, II, III, and IV. Referring to FIGS. 2 and 3A, the lens 225 has a focal length of 164 mm according to one embodiment. In this example, the scanner 220 then has a scan area of about 80 mm×80 mm, and the laser source 210 provides a pulse having a pulse width of about 1.5 μs or greater having a total energy of from about 4 to about 6 mJ/pulse. As such, only a single pulse is required to drill each hole through the substrate 240 having a thickness of less than 300 μm.

As shown in FIG. 3, the scanner 220 forms a pattern 310 of holes through the quadrant I of the substrate 240. In one example, the holes have a diameter of between about 40 and 70 μm. The scanner 220 speed is about 3750 mm/s, and the laser pulse repetition rate is about 15 kHz. After forming the pattern 310 of holes in quadrant I, the scanner 220 is positioned to form the pattern 310 of holes in quadrant II of the substrate 240. In one embodiment, the scanner 220 is moved into position over quadrant II via the positioning gantry 230. In another embodiment, the substrate 240 is moved via the positioning table 250, such that the scanner 220 is positioned over quadrant II of the substrate 240. Then, the scanner forms the pattern 310 of holes through quadrant II of the substrate 240 using the above described parameters. The process of positioning the scanner 220 or the substrate 240 is then repeated as described above for drilling the pattern 310 of holes in quadrants III and IV of the substrate 240. Thus, a pattern of holes across the entire substrate 240 is drilled for subsequent use in fabrication of an EWT solar cell using a only a single pulse for each hole. In this example, it was found that a processing time for the entire substrate 240 of about 6.5 seconds was achieved.

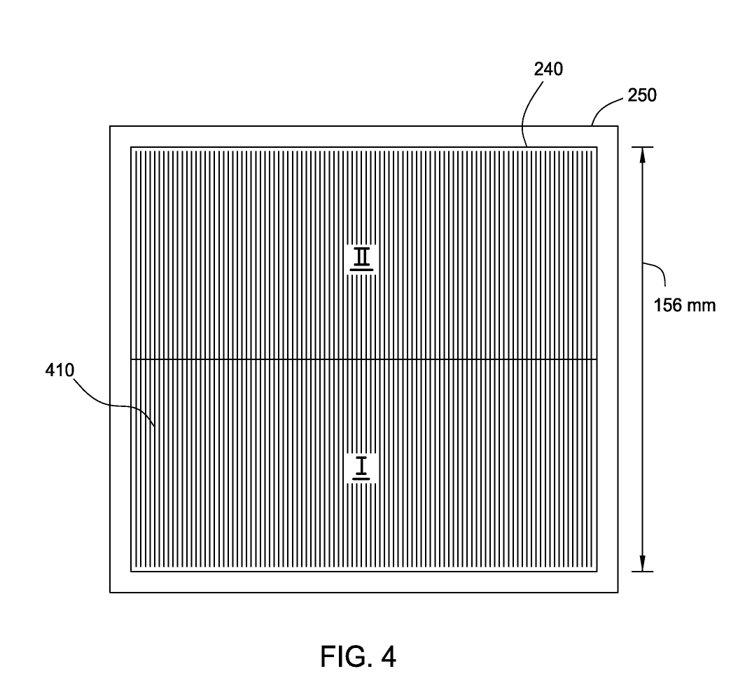

FIG. 4 is a schematic, top view of the substrate 240 positioned on the positioning table 250 for use in performing a process according to another embodiment. As in the first example, the substrate 240 is a 156 mm×156 mm silicon substrate having a thickness of between about 150 μm to about 300 μm. The substrate 240 is schematically shown divided into halves I and II. Referring to FIGS. 2 and 4, the lens 225 has a focal length of 164 mm according to this embodiment. As in the first example, the scanner 220 has a scan area of about 80 mm×80 mm, which covers approximately one quarter of the substrate 240. As in the first example, only a single pulse is required to drill each hole through the substrate 240 having a thickness of less than 300 μm.

In contrast to the first example described with respect to FIG. 3, the present example provides relative movement between the scanner 220 and the substrate 240 in the X-direction while a pattern 410 of holes is being drilled through the substrate 240. In one embodiment, the relative movement is provided by the positioning gantry 230 moving the scanner 220 during drilling the pattern 410 of holes. In another embodiment, the relative movement is provided by the positioning table 250 during drilling the pattern of holes. As a result, the pattern 410 covers the entire half I of the substrate 240. In this example, the holes have a diameter of between about 40 and 70 μm. The scanner 220 speed is about 3750 mm/s, and the laser pulse repetition rate is about 15 kHz. After forming the pattern 410 of holes in half I, the scanner 220 is positioned to form the pattern 410 of holes in half II of the substrate 240. In one embodiment, the scanner 220 is moved into position over half II via the positioning gantry 230. In another embodiment, the substrate 240 is moved via the positioning table 250, such that the scanner 220 is positioned over half II of the substrate 240. Then, the scanner forms the pattern 410 of holes through half II of the substrate 240 using the above described parameters. Thus, a pattern of holes across the entire substrate 240 is drilled for subsequent use in fabrication of an EWT solar cell using a only a single pulse for each hole. In this example, it was found that a processing time for the entire substrate 240 of about 5.5 s was achieved.

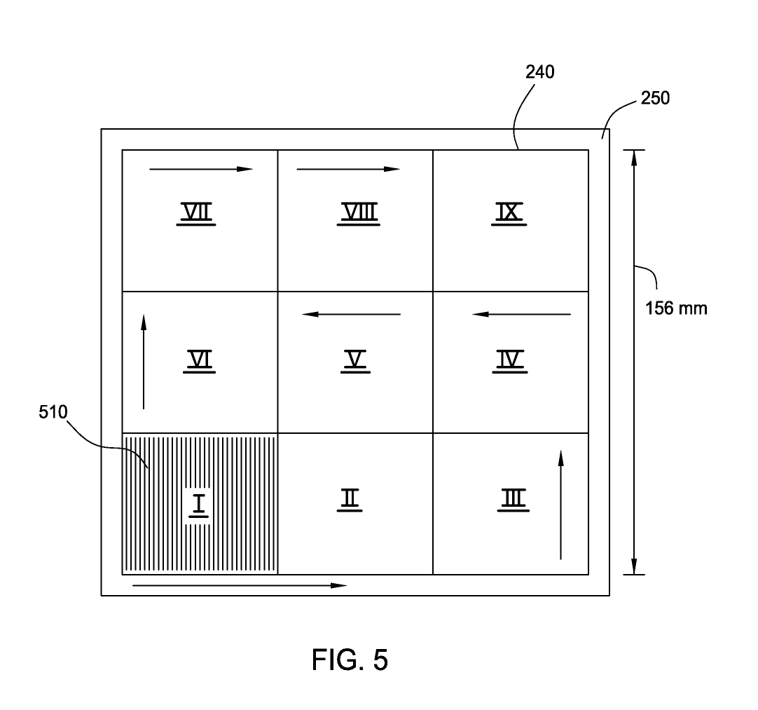

FIG. 5 is a schematic, top view of the substrate 240 positioned on the positioning table 250 for use in performing a process according to another embodiment. As in the previous examples, the substrate 240 is a 156 mm×156 mm silicon substrate having a thickness of between about 150 μm to about 300 μm. The substrate 240 is schematically shown divided into sections I-IX. Referring to FIGS. 2 and 5, the lens 225 has a focal length of 100 mm according to this embodiment. As in the first example, the scanner 220 has a scan area of about 55 mm×55 mm, which covers approximately 1/9 of the substrate 240. As in the first two examples, only a single pulse is required to drill each hole through the substrate 240 having a thickness of less than about 300 μm.

As shown in FIG. 5, the scanner 220 forms a pattern 510 of holes through the section I of the substrate 240. In this example, the holes have a diameter of between about 40 and 70 μm. The scanner 220 speed is about 3750 mm/s, and the laser pulse repetition rate is about 15 kHz. After forming the pattern 510 of holes in section I, the scanner 220 is positioned to form the pattern 310 of holes in section II of the substrate 240. In one embodiment, the scanner 220 is moved into position over section II via the positioning gantry 230. In another embodiment, the substrate 240 is moved via the positioning table 250, such that the scanner 220 is positioned over section II of the substrate 240. Then, the scanner forms the pattern 510 of holes through section II of the substrate 240 using the above described parameters. The process of positioning the scanner 220 or the substrate 240 is then repeated as described above for drilling the pattern 510 of holes in sections III-IX of the substrate 240. Thus, a pattern of holes across the entire substrate 240 is drilled for subsequent use in fabrication of a EWT solar cell using a only a single pulse for each hole. In this example, it was found that a processing time for the entire substrate 240 of about 9 s was achieved.

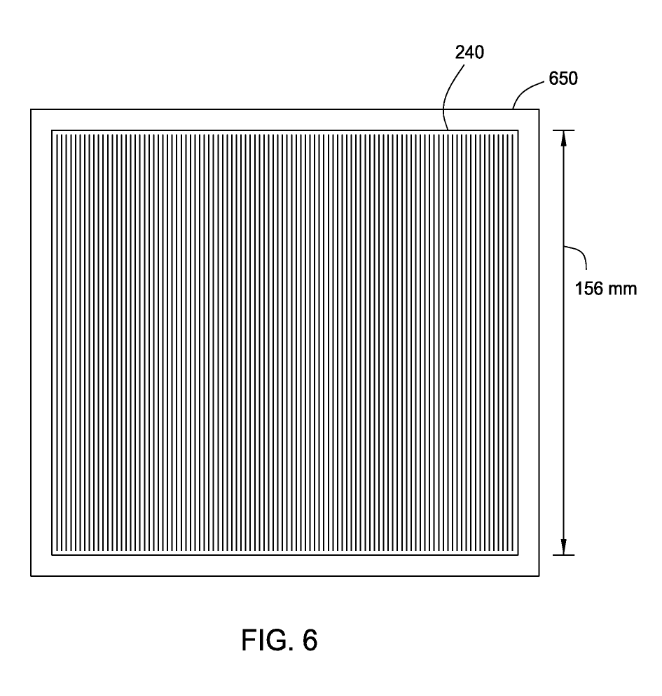

For comparison, a conventional setup using a lens having a focal length of 254 mm was used. FIG. 6 is a schematic, top view of the substrate 240 positioned on a stationary table 650 for illustration of this example. In this example, the scan area covered the entire area of the 156 mm×156 mm substrate 240. The scanner speed and pulse repetition rate were identical to that described with respect to FIG. 3. Because of the longer focal length of the lens, it required 4 pulses to drill each hole. In this example, it was found that a processing time for the entire substrate 240 was about 17.5 s.

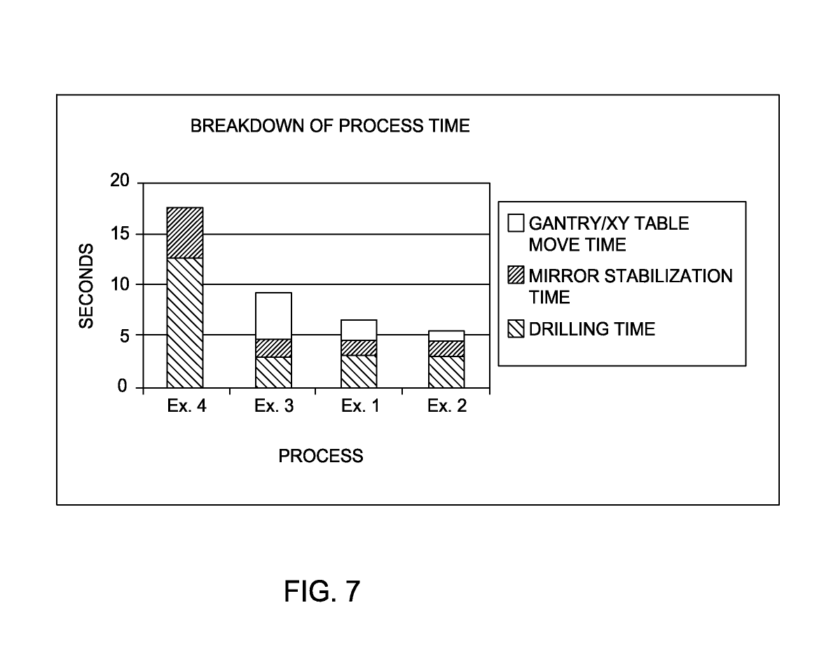

FIG. 7 is a chart comparing the processing times of the processes described in examples 1-4 with respect to FIGS. 3-6. Example 1 refers to the example described above with respect to FIG. 3. Example 2 refers to the example described above with respect to FIG. 4. Example 3 refers to the example described above with respect to FIG. 5. Example 4 refers to the example described above with respect to FIG. 6 using conventional processes and apparatus. Drilling time refers to the total time spent drilling the pattern of holes over the entire substrate. Mirror stabilization time refers to the total time spent accelerating and decelerating the mirrors in the scanner at the end and beginning of each line of holes. As can be seen in FIG. 7, the processes of the present invention yield dramatic time savings due to the single pass nature of the drilling processes.

Although the invention has been described in detail with particular reference to these preferred embodiments, other embodiments can achieve the same results. Variations and modifications of the present invention will be obvious to those skilled in the art and it is intended to cover all such modifications and equivalents. The entire disclosures of all patents, references, and publications cited above are hereby incorporated by reference.

1. A method of forming holes through a substrate, comprising:
forming a first pattern of holes through the substrate within a first section of the surface of the substrate using a laser scanner;
positioning the laser scanner over a second section of the surface of the substrate adjacent the first section; and
forming a second pattern of holes through the substrate within the second section, wherein each hole is formed with a single laser pulse.

2. The process of claim 1, wherein the laser scanner has a lens configured such that the resulting scan area is substantially less than the area of the surface of the substrate.

3. The process of claim 2, wherein the laser scanner has a lens configured such that the resulting scan area is less than half of the area of the surface of the substrate.

4. The process of claim 3, further comprising moving the substrate during forming the first and second pattern of holes.

5. The process of claim 3, wherein positioning the laser scanner over the second section comprises moving the substrate relative to the scanner.

6. The process of claim 3, wherein positioning the laser scanner over the second section comprises moving the laser scanner.

7. The method of claim 3, further comprising:
positioning the laser scanner over a third section of the surface of the substrate adjacent the second section; and
forming a third pattern of holes through the substrate within the third section.

8. The method of claim 3, wherein each hole has a diameter of between about 40 μm and about 70 μm.

9. The method of claim 3, wherein the substrate has a width of about 156 mm, a length of about 156 mm, and a thickness of about 0.3 mm.

10. An apparatus for forming a pattern of holes through a substrate, comprising:
a system controller;
a positioning table configured move the substrate within a plane, wherein movement of the substrate is controlled by instructions from the system controller;
a laser scanner configured with a scan area that is substantially less than the surface area of the substrate, wherein the laser scanner is configured to form a pattern of holes through the substrate within a first section of a surface area of the substrate without moving the substrate or the laser scanner, wherein the laser scanner comprises:
a laser source; and
a lens disposed between the laser and the substrate, wherein the system controller controls the laser source to transmit electromagnetic energy through the lens such that each hole is formed with a single laser pulse.

11. The apparatus of claim 10, wherein the lens has a focal length of approximately 163 mm.

12. The apparatus of claim 10, wherein the lens has a focal length of approximately 100 mm.

13. The apparatus of claim 10, further comprising a positioning gantry configured to move the laser scanner.

14. The apparatus of claim 10, wherein the laser is configured to deliver the electromagnetic energy at a wavelength of about 1030 nm.
